(19) United States
(12) Patent Application Publication
(10) Pub. No.: US 2022/0206441 A1
(43) Pub. Date: Jun. 30, 2022

(54) CHIP ATOMIC CLOCK MICROSYSTEM BASED ON NANO Y WAVEGUIDE

(71) Applicant: Zhejiang University of Water Resources and Electric Power, Hangzhou (CN)

(72) Inventors: Shubin Yan, Hangzhou (CN); Xiushan Wu, Hangzhou (CN); Ertian Hua, Hangzhou (CN); Yunxia Luo, Hangzhou (CN)

(21) Appl. No.: 17/134,159

(22) Filed: Dec. 24, 2020

(51) Int. Cl. G04F 5/14; B81B 7/02

(52) U.S. Cl. CPC G04F 5/14; B81B 7/02

(57) ABSTRACT

The present invention discloses a chip atomic clock microsystem based on a nano Y waveguide, including a magnetic shielding portion, an optical system and a physical system. The optical system and the physical system are arranged in a magnetic shielding layer. The unique nano Y waveguide and nano vertical coupling gratings used in the optical system greatly improve the photoelectric conversion efficiency and a space utilization rate, and reduce the size of the atomic clock. In addition, especially the two-layer magnetic shielding design is adopted, which effectively improves the shielding effect. The chip atomic clock microsystem based on a nano Y waveguide according to the present invention has the advantages of being easy to mount, stable in performance, compact in structure, small in size, low in power consumption, long in service life and high in precision.

### TECHNICAL FIELD

The present invention relates to the field of atomic clocks, and in particular, to a chip atomic clock microsystem based on a nano Y waveguide.

### BACKGROUND

A chip atomic clock is a precise time measuring instrument for timing by using electromagnetic waves emitted when atoms absorb or release energy. A high-precision atomic clock based on an MEMS technology combined with a micro-positioning navigation and timing (PNT) system composed of micro inertial measurement units is combined with a satellite navigation technology to form a micro-PNT unit, which can be widely used in satellite navigation receivers, micro unmanned aerial vehicles, underwater communication equipment, precision guided weapons, industry and agriculture, to solve the PNT problems in the fields of military affairs, scientific research, measurement, aviation, aerospace, meteorology, resources, communication, geodesy, etc. The atomic clock has the important characteristics of comprehensive information, complete autonomy, real-time and continuous information, and no susceptibility to time and geographical restrictions. At present, elements used in atomic clocks include rubidium (Rb), cesium (Cs) and other alkali metal elements, and the accuracy can reach an error of 1 s every 60 million years, which provides a strong guarantee for aviation, aerospace and navigation.

The basic principle of the chip atomic clock is that coherent light couples two hyperfine energy levels of an atomic ground state to a common excited state, and when the frequency difference of coherent two-color light is strictly equal to the two hyperfine energy levels of the atomic ground state, some atoms no longer absorb photons and are prepared into a coherent population trapping (CPT) state. After probe light interacts with atoms, an absorption signal of the atoms absorbing laser is obtained, and an electromagnetic induction transparent spectral line generated by CPT resonance in the absorption signal is used as a microwave frequency discrimination signal, which is converted into a frequency correction signal to carry out negative feedback correction on a voltage-controlled crystal oscillator, so that an output frequency signal of the atomic clock with high stability can be obtained.

The vibration frequency of the chip atomic clock is determined by the transition frequency of the atomic hyperfine energy level compared with that of a conventional crystal oscillator, so the chip atomic clock not only retains the characteristics of high precision of an atomic frequency standard to a certain extent, but also has higher frequency accuracy and frequency stability than the commonly used crystal oscillator by several orders of magnitude, and has the advantages of low power consumption and small size. These excellent characteristics mainly depend on its internal physical system. The existing chip atomic clock physical system does not have the characteristics of small size and low power consumption, and the positioning accuracy and timing capability also need to be further improved, which leads to the failure to expand the application of the atomic clock to various high-security ultrahigh-frequency communication, global positioning system receivers and other battery-powered portable electronic devices and the failure to improve the performance of the devices.

Therefore, a chip atomic clock micro-physical system with compact structure, long service life, small size, low power consumption and high stability is needed.

### SUMMARY

In order to solve the disadvantages of the prior art, the present invention provides a chip atomic clock microsystem based on a nano Y waveguide with small size, low power consumption and high stability.

To achieve the foregoing objective, the present invention adopts the following technical solutions: A chip atomic clock microsystem based on nano Y waveguide, including a magnetic shielding portion, an optical system and a physical system, where

the magnetic shielding portion includes an external magnetic shielding housing and an internal magnetic shielding housing, and the external magnetic shielding housing is internally provided with a printed circuit board (PCB); a voltage control module, a vertical cavity surface emitting laser (VCSEL) current control module, a radio frequency control module and a temperature control module are mounted on the PCB, and a panel below the internal magnetic shielding housing is provided with outline openings of two nano vertical coupling gratings;

the optical system includes a VCSEL, a micro-optical lens group and a nano waveguide functional unit; the micro-optical lens group includes three lenses, namely an attenuation slice, a polarizer and a λ/4 wave plate; the nano waveguide functional unit includes a phase modulation unit, nano vertical coupling gratings and a nano Y waveguide, the nano vertical coupling gratings are respectively located at a bifurcated end and an end of the nano Y waveguide; the phase modulation unit is located on one branch of the nano Y waveguide; the voltage control module and the VCSEL current control module are connected to the VCSEL, and the radio frequency control module is connected to the phase modulation unit; the nano Y waveguide is mounted and fixed on the PCB; the attenuation slice, the polarizer and the λ/4 wave plate are sequentially mounted on a PCB bracket from top to bottom, and the VCSEL is bonded on a space bracket above the attenuation slice; the VCSEL, the attenuation slice, the polarizer, the λ/4 wave plate and the nano vertical coupling gratings at an end of the nano Y waveguide are on the same vertical optical path; and

the physical system includes photoelectric converters, C-field coils, polyimide insulation layers, ITOs and an MEMS micro gas chamber; one C-field coil, one polyimide insulation layer and one ITO are sequentially arranged above the MEMS micro gas chamber from top to bottom, and one ITO, one polyimide insulation layer and one C-field coil are sequentially arranged below the MEMS micro gas chamber from top to bottom; the C-field coils above the MEMS micro gas chamber is provided with two photoelectric converters, the physical system is arranged in the internal magnetic shielding housing, and the temperature control module is connected to the ITO; and the outline openings of the panel below the internal magnetic shielding housing are respectively clamped on the two nano vertical coupling gratings at the bifurcated end of the nano Y waveguide.

The VCSEL is configured to emit linearly polarized light, the attenuation slice is configured to attenuate light intensity, the polarizer is configured to determine the polarization direction of light, the λ/4 wave plate is configured to convert the linearly polarized light into circularly polarized light, and the nano waveguide functional unit divides, by using the nano vertical coupling grating and the nano Y waveguide, the linearly polarized light emitted by the VCSEL and the circularly polarized light converted after passing through the lens group into two beams with the same intensity, one of which is used as reference light, the other beam enters the physical system after passing through the phase modulation unit. After passing through the same detection unit, i.e., the photoelectric converter, the two beams enter a subtraction unit for subtraction to obtain a transition signal of the atomic clock.

In the chip atomic clock microsystem based on a nano Y waveguide, encapsulation steps are as follows: (1) the nano Y waveguide is mounted and fixed above the PCB; (2) the attenuation slice, the polarizer and the λ/4 wave plate are sequentially mounted on the circuit board bracket from top to bottom, and an included angle between an optical axis of the λ/4 wave plate and a polar axis of the VCSEL is 45°; (3) the space bracket is provided with a pad of the VCSEL and a pad of a thermistor, the VCSEL and the thermistor are mounted on the space bracket, and the space bracket and the adjusted micro-optical lens group are welded by using an indium wire to form a complete and fixed structure; (4) fixing of the MEMS micro gas chamber to the ITO and the polyimide insulation layer: the MEMS micro gas chamber, the ITO and a polyimide insulation layer optical path are aligned with each other by using the laser, and the MEMS micro gas chamber and these components are fixed together by ultraviolet curing glue; (5) after the above components are equipped, a PCB circuit and a chip of each control module are electrified and connected to an encapsulation tube base, and then all electrical connections therein are tested; (6) transmittance and a rubidium absorption curve of core components are tested; (7) when the transmittance and the rubidium absorption curve are good, the C-field coils are mounted with ultraviolet curing glue; (8) conductive adhesive is applied to a slide of C-field coil, and the photoelectric converters are fixed to the slide; (9) then the transmittance and the rubidium absorption curve are tested again; if the above tests are passed normally, vacuum encapsulation is performed by using the external magnetic shielding housing and the internal magnetic shielding housing, and then the overall performance is tested.

In the chip atomic clock microsystem based on a nano Y waveguide, there is one turn of C-field coil, such that a current passing through the coil can be greatly reduced, thereby minimizing the power consumption of the physical encapsulation.

In the chip atomic clock microsystem based on a nano Y waveguide, the C-field coil, the polyimide insulation layer, the ITO and the MEMS micro gas chamber are each set into a rectangular sheet structure with the same size, which is favorable for alignment between layers and facilitates mounting; and the C-field coil is a Helmholtz coil, which is matched with the shape of the MEMS micro gas chamber, thereby improving the performance of the chip atomic clock.

In the chip atomic clock microsystem based on a nano Y waveguide, the MEMS micro gas chamber is implemented by using an anodic bonding process and is filled with buffer gas, and the buffer gas has functions of fluorescence quenching and narrowing of a spectral line width; and the buffer gas may be a mixed gas of N₂ and argon, or a mixed gas of neon and argon.

The chip atomic clock microsystem based on a nano Y waveguide further includes a bottom plate with supporting legs, where the microsystem can be placed on the bottom plate.

The structure of the chip atomic clock microsystem based on a nano Y waveguide is a microstructure based on the interaction between atoms and coherent two-color light, resulting in CPT. The structure uses the nano waveguide functional unit, the MEMS micro gas chamber, double-layer shielding design, multi-functional integrated circuit chips and improved overall encapsulation steps of the system, and has the following advantages:

(1) The use of the nano Y waveguide and the nano vertical coupling grating reduces the impact of optical power fluctuation and frequency fluctuation noise, and the adverse impact of background noise on short-term stability is also greatly weakened, which solves the problem of low photoelectric conversion transmission efficiency, reduces space waste, improves the space utilization rate of the chip atomic clock, and achieves the purpose of small size and low power consumption of the chip atomic clock.

(2) The MEMS micro gas chamber replaces a microwave cavity in conventional design. Anodic bonding and an MEMS process can significantly reduce the size of the chip atomic clock, so that the chip atomic clock can be portably applied to high-precision devices with size requirements.

(3) Double-layer shielding design is used, and one-time molding is performed by a 3D printing technology, so that the shielding effect is effectively improved, and the impact of insufficient single-layer shielding effect on the performance of the whole machine is avoided.

(4) The multi-functional integrated circuit chips are divided into four modules, namely a voltage control module, a VCSEL current control module, a radio frequency control module and a temperature control module, which are mutually independent and interrelated. These chips can not only independently control a certain part, but also form a complete servo loop.

(5) Through improvements of overall encapsulation steps of the system, components are placed layer by layer, which makes the structure firm and compact, effectively improves the space utilization rate and reduces the size of the atomic clock.

### BRIEF DESCRIPTION OF THE DRAWINGS

FIG. 1 is a schematic diagram of overall encapsulation of a chip atomic clock microsystem with double optical paths based on a nano Y waveguide;

FIG. 2 is an exploded view of each part of a chip atomic clock microsystem with double optical paths based on a nano Y waveguide;

FIG. 3 is a schematic diagram of a nano waveguide functional unit; and

FIG. 4 is a schematic cross-sectional diagram of an MEMS micro gas chamber.

In the figures: 1. magnetic shielding portion, 2. optical system, 3. nano waveguide functional unit, 4. physical system, 5. external magnetic shielding housing, 6. internal magnetic shielding housing, 7. micro-optical lens group, 8. voltage control module, 9. VCSEL current control module, 10. radio frequency control module, 11. phase modulation unit, 12. temperature control module, 13. bottom plate, 14. internal magnetic shielding housing, 15. photoelectric converter, 16. C-field coil, 17. polyimide insulation layer, 18. ITO, 19. MEMS micro gas chamber, 20. nano vertical coupling grating, 21. nano Y waveguide, 22. PCB, 23. alkali metal atomic gas chamber, 24. glass, 25. Si, 26. ⁸⁷Rb atoms, 27. gas chamber microchannel, 28. reaction residue.

### DESCRIPTION OF THE EMBODIMENTS

The present invention is further described below with reference to the accompanying drawings. In the drawings, the same parts are denoted by the same reference numerals.

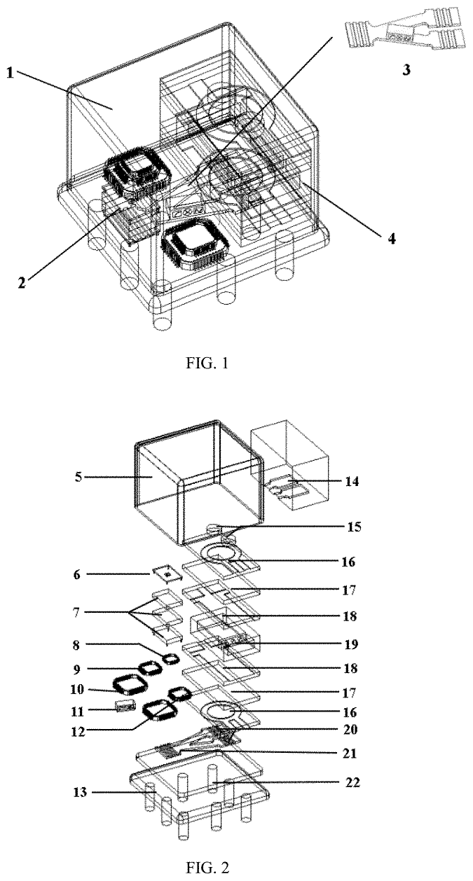

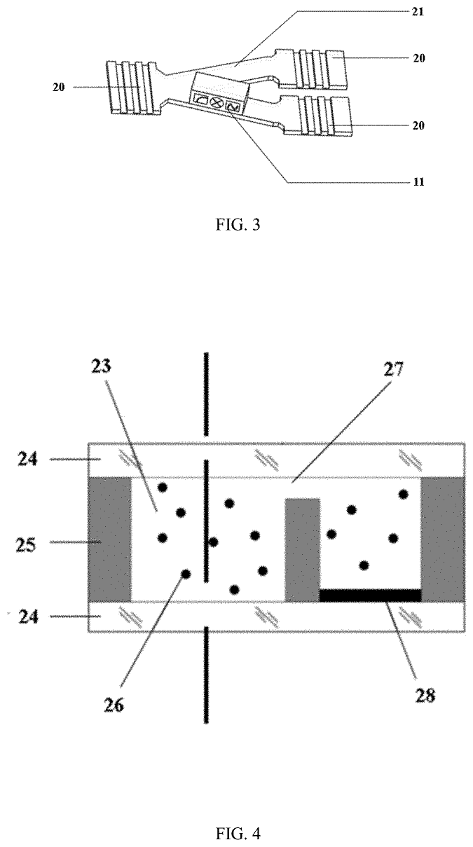

FIGS. 1 and FIG. 2 are schematic diagrams of a physical encapsulation structure of a chip atomic clock microsystem based on a nano Y waveguide, mainly including a magnetic shielding portion 1, an optical system 2 and a physical system 4.

The magnetic shielding portion 1, namely an external magnetic shielding housing 5 and an internal magnetic shielding housing 14, are molded in one time by using a 3D printing technology and sealed by a welding process, such that they have good gas tightness and shielding performance, especially the inner and outer shielding design, which effectively improves the shielding effect. Especially, the height of the internal magnetic shielding housing 14 is matched with the height of the internal core component, and the top of the physical system 4 is connected to the internal magnetic shielding housing, which ensures that the mechanical structure of the internal system is not easy to break and separate and has good impact resistance.

The optical system 2 includes a VCSEL 6, a micro-optical lens group 7 and a nano waveguide functional unit 3. The VCSEL 6 is bonded to a space bracket above the micro-optical lens group 7 and configured to emit linearly polarized light, and the space bracket can provide a free space for the linearly polarized laser, and make the laser diverge to a predetermined light spot size. The micro-optical lens group 7 is composed of three lenses, namely an attenuation slice, a polarizer and a λ/4 wave plate. The attenuation slice is configured to attenuate light intensity, the polarizer is configured to determine the polarization direction of light, and the λ/4 wave plate is configured to convert the linearly polarized light into circularly polarized light. The attenuation slice, the polarizer and the λ/4 wave plate are welded and fixed with an indium wire to form an enclosed space inside, which reduces the heat loss caused by gas flow, so that a VCSEL current control module 9 and a temperature control module 12 can work independently and ensure the performance stability of the whole chip atomic clock. The nano waveguide functional unit 3 is composed of a phase modulation unit 11, nano vertical coupling gratings 20 and a nano Y waveguide 21. The functional unit divides, by using the nano vertical coupling grating 20 and the nano Y waveguide 21, the linearly polarized light emitted by the VCSEL 6 and the circularly polarized light converted after passing through the lens group 7 into two beams with the same intensity, one of which is used as reference light, the other beam enters the physical system 4 after passing through the phase modulation unit 11. After passing through the same detection unit, i.e., a photoelectric converter 15, the two beams enter a subtraction unit for subtraction to obtain a transition signal of the atomic clock.

The physical system 4 includes the photoelectric converter 15, C-field coils 16, polyimide insulation layers 17, ITOs 18 and an MEMS micro gas chamber 19. The constant and uniform C-field required for energy level splitting of atoms can be generated by a group of coils. In the present invention, there is one turn of C-field coil 16, such that a current passing through the coil can be greatly reduced, thereby minimizing the power consumption of the physical encapsulation. The polyimide insulation layer 17 reduces heat conduction and heat loss, thus reducing the overall power consumption of the chip atomic clock system. A thermistor is fixed on the ITO 18 by using a pad, the ITO 18 controls the heating of the MEMS micro gas chamber 19 by using the pad through the temperature control module 12, and the thermistor thereon can acquire temperature data at the same time and feed temperature signal data back to the temperature control module 12, so as to control the temperature of the MEMS micro gas chamber 19. The MEMS micro gas chamber 19 is implemented by using an anodic bonding process and is filled with ⁸⁷Rb atoms and buffer gas. The buffer gas has the functions of fluorescence quenching and narrowing of a spectral line width. The buffer gas may be a mixed gas of N₂ and argon, or a mixed gas of neon and argon. The C-field coil 16, the polyimide insulation layer 17, the ITO 18 and the MEMS micro gas chamber 19 are each set into a rectangular sheet structure with the same size and are made of a transparent material, which is favorable for alignment between layers and facilitates mounting; and the C-field coil 16 is a Helmholtz coil, which is matched with the shape of the MEMS micro gas chamber 19, thereby improving the performance of the chip atomic clock.

The nano Y waveguide in the optical system 2 splits the light emitted by the VCSEL, and needs to be tightly connected to each optical path portion in the process of encapsulation of a physical portion, thus reducing the size of the chip atomic clock. In addition, the impact of optical power fluctuation and frequency fluctuation noise is also greatly reduced, and the adverse impact of background noise on short-term stability is also greatly weakened. The application of the nano vertical coupling grating 20 solves the problem of low photoelectric conversion transmission efficiency, improves the space utilization rate of the chip atomic clock, and achieves the purpose of small size and low power consumption of the chip atomic clock.

The overall encapsulation steps of the system are as follows.

(1) The nano Y waveguide 21 is mounted and fixed above the PCB 22; (2) the attenuation slice, the polarizer and the λ/4 wave plate are sequentially mounted on a bracket from top to bottom, and it should be particularly noted that an included angle between an optical axis of the λ/4 wave plate and a polar axis of the VCSEL is 45°, and the distance between the lenses is adjusted carefully; (3) encapsulation and electrical testing of the VCSEL system: a pad of the VCSEL 6 and a pad of a thermistor are fixed to the space bracket, the VCSEL 6 and the thermistor are mounted on the space bracket, and the space bracket and the adjusted micro-optical lens group 7 are welded by using an indium wire to form a complete and fixed structure; (4) fixing of the MEMS micro gas chamber 19 to the ITO 18 and the polyimide insulation layer 17: the MEMS micro gas chamber, the ITO and a polyimide insulation layer optical path are aligned with each other by using the laser, and the MEMS micro gas chamber and these components are fixed together by ultraviolet curing glue, that is, a small amount of glue solution is added dropwise on the surface of the gas chamber, and an area coated with the curing glue is irradiated with an ultraviolet lamp with a wavelength of 365 nm for solidification; (5) after the above core components are equipped, a PCB circuit and a chip of each control module are electrified and connected to an encapsulation tube base, and then all electrical connections therein are tested; (6) transmittance and a rubidium absorption curve of core components are tested; (7) when the transmittance and the rubidium absorption curve are good, the C-field coils 16 are mounted with ultraviolet curing glue; (8) an anode of the photoelectric converter 15 is on the back, and the photoelectric converters 15 are fixed to the slide; (9) then the transmittance and the rubidium absorption curve are tested again; if the above tests are passed normally, vacuum encapsulation is performed, and then the overall performance is tested.

It can be seen from the technical solution that in the present invention, the optimized design of miniaturization of the physical system under the condition of the existing micromachining technology is implemented.

What is claimed is:

1. A chip atomic clock microsystem based on a nano Y waveguide, comprising a magnetic shielding portion (1), an optical system (2) and a physical system (4); wherein
the magnetic shielding portion (1) comprises an external magnetic shielding housing (5) and an internal magnetic shielding housing (14), and the external magnetic shielding housing (5) is internally provided with a printed circuit board (PCB) (22); a voltage control module (8), a vertical cavity surface emitting laser (VCSEL) current control module (9), a radio frequency control module (10) and a temperature control module (12) are mounted on the PCB (22), and a panel below the internal magnetic shielding housing (14) is provided with outline openings of two nano vertical coupling gratings;
the optical system (2) comprises a VCSEL (6), a micro-optical lens group (7) and a nano waveguide functional unit (3); the micro-optical lens group (7) comprises three lenses, namely an attenuation slice, a polarizer and a λ/4 wave plate; the nano waveguide functional unit (3) comprises a phase modulation unit (11), nano vertical coupling gratings (20) and a nano Y waveguide (21), the nano vertical coupling gratings (20) are respectively located at a bifurcated end and an end of the nano Y waveguide (21); the phase modulation unit (11) is located on one branch of the nano Y waveguide (21); the voltage control module (8) and the VCSEL current control module (9) are connected to the VCSEL (6), and the radio frequency control module (10) is connected to the phase modulation unit (11); the nano Y waveguide (21) is mounted and fixed on the PCB (22); the attenuation slice, the polarizer and the λ/4 wave plate are sequentially mounted on a PCB (22) bracket from top to bottom, and the VCSEL (6) is bonded on a space bracket above the attenuation slice; and
the physical system (4) comprises photoelectric converters (15), C-field coils (16), polyimide insulation layers (17), ITOs (18) and an MEMS micro gas chamber (19); one C-field coil (16), one polyimide insulation layer (17) and one ITO (18) are sequentially arranged above the MEMS micro gas chamber (19) from top to bottom, and one ITO (18), one polyimide insulation layer (17) and one C-field coil (16) are sequentially arranged below the MEMS micro gas chamber (19) from top to bottom; the C-field coils (16) above the MEMS micro gas chamber (19) is provided with two photoelectric converters (15), the physical system (4) is arranged in the internal magnetic shielding housing (14), and the temperature control module (12) is connected to the ITO (18); and the outline openings of the panel below the internal magnetic shielding housing (14) are respectively clamped on the two nano vertical coupling gratings (20) at the bifurcated end of the nano Y waveguide (21).

2. The chip atomic clock microsystem based on a nano Y waveguide according to claim 1, wherein encapsulation steps are as follows: (1) the nano Y waveguide (21) is mounted and fixed above the PCB (22); (2) the attenuation slice, the polarizer and the λ/4 wave plate are sequentially mounted on the circuit board bracket from top to bottom; (3) the space bracket above the attenuation slice is provided with a pad of the VCSEL (6) and a pad of a thermistor, the VCSEL (6) and the thermistor are mounted on the space bracket, and the space bracket and the adjusted micro-optical lens group (7) are welded by using an indium wire to form a complete and fixed structure; (4) fixing of the MEMS micro gas chamber (19) to the ITO (18) and the polyimide insulation layer (17): the MEMS micro gas chamber, the ITO and a polyimide insulation layer optical path are aligned with each other by using the laser, and the MEMS micro gas chamber and these components are fixed together by ultraviolet curing glue;
(5) after the above components are equipped, a PCB circuit and a chip of each control module are electrified and connected to an encapsulation tube base, and then all electrical connections therein are tested; (6) transmittance and a rubidium absorption curve of core components are tested; (7) when the transmittance and the rubidium absorption curve are good, the C-field coils (16) are mounted with ultraviolet curing glue; (8) conductive adhesive is applied to a slide of C-field coil, and the photoelectric converters (15) are fixed to the slide; (9) then the transmittance and the rubidium absorption curve are tested again; if the above tests are passed normally, vacuum encapsulation is performed by using the external magnetic shielding housing (5) and the internal magnetic shielding housing (14), and then the overall performance is tested.

3. The chip atomic clock microsystem based on a nano Y waveguide according to claim 1, wherein there is one turn of C-field coil (16), such that a current passing through the coil can be greatly reduced, thereby minimizing the power consumption of the physical encapsulation.

4. The chip atomic clock microsystem based on a nano Y waveguide according to claim 1, wherein the C-field coil (16), the polyimide insulation layer (17), the ITO (18) and the MEMS micro gas chamber (19) are each set into a rectangular sheet structure with the same size, which is favorable for alignment between layers and facilitates mounting; and the C-field coil (16) is a Helmholtz coil, which is matched with the shape of the MEMS micro gas chamber (19), thereby improving the performance of the chip atomic clock.

5. The chip atomic clock microsystem based on a nano Y waveguide according to claim 1, wherein the MEMS micro gas chamber (19) is implemented by using an anodic bonding process and is filled with buffer gas, and the buffer gas has functions of fluorescence quenching and narrowing of a spectral line width; and the buffer gas may be a mixed gas of N₂ and argon, or a mixed gas of neon and argon.

6. The chip atomic clock microsystem based on a nano Y waveguide according to claim 1, further comprising a bottom plate (13) with supporting legs.
